(19) United States
(12) Patent Application Publication
(10) Pub. No.: US 2023/0215493 A1
(43) Pub. Date: Jul. 6, 2023

(54) CROSS DRAM DIMM SUB-CHANNEL PAIRING

(71) Applicant: Intel Corporation, Santa Clara, CA (US)

(72) Inventors: Duane E. GALBI, Wayland, MA (US); Matthew J. ADILETTA, Bolton, MA (US); Mohammad M. RASHID, San Jose, CA (US); Todd HINCK, Arlington, MA (US); Vijaya K. BODDU, Pleasanton, CA (US)

(21) Appl. No.: 18/120,907

(22) Filed: Mar. 13, 2023

(51) Int. Cl. G11C 11/4093; G11C 11/4076; G11C 5/06; G11C 11/4096

(52) U.S. Cl. CPC G11C 11/4093; G11C 11/4076; G11C 5/06; G11C 11/4096

(57) ABSTRACT

Methods and apparatus for Cross DRAM DIMM sub-channel pairing. Memory channels on a memory controller or System on a Chip (SoC) are segmented into two subchannels, each including Command and Address (C/A) signals, DQ (data) lines. Under different solutions the two subchannels may share a command-bus clock or use separate command-bus clocks. Some approaches use subchannels from different memory channels to provide the C/A and DQ lines for two subchannels to a given DIMM. One solution implements an additional command-bus clock on the DIMM connector repurposing existing MCR pins to provide command-bus clock signals to a Registered Clock Driver (RCD) to allow the subchannels to be fully independent. Another solution is the pair every other DRAM controller to the same command-bus clock. Other solutions employ Skip-1, Skip-2, and Skip-3 configurations under which the clocks for the DDR-IO circuitry are not logically co-located with the subchannel IO circuitry.

### BACKGROUND INFORMATION

The number of Central Processing Units (CPUs) per server socket and the memory bandwidth per CPU have both been increasing over time. This has required an increased number of memory channels per server socket. Each one of the memory channels connects to one of more external memory DRAM DIMMs (Dynamic Random Access Memory Dual Inline Memory Modules). Routing all the memory channel signals from the chip input and outputs (“IO”) to the external memory s has become increasingly complicated with the increase in the number of memory channels. This has resulted in an increase in the number of required signal layers on both the socket package and the system board and a corresponding increase in cost of these components. The more complicated routing also makes it more difficult match the routing of the signals and hence reduces the timing margin on the routed signals.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram illustrating selective elements in a memory subsystem including a memory controller coupled to a DIMM showing two ranks of DRAM devices;

FIG. 2 is a diagram illustrating an example system including a memory controller with first and second memory channels;

FIG. 3 is a schematic diagram of a first sub-channel solution under which the subchannels for respective memory channels are provided to the same DRAM DIMMs, according to one embodiment;

FIG. 4 is a schematic diagram of a second sub-channel solution that employs a pair of command-bus clocks for each DRAM DIMM, enabling the subchannels to be operated independently, according to one embodiment;

FIG. 5 is a schematic diagram of a third sub-channel solution under which the subchannels and the command-bus clocks of the DDR-IO circuitry for respective memory channels are routed to different DIMMs, according to one embodiment.

FIG. 6 is a schematic diagram of a fourth sub-channel solution employing a “Skip-1” configuration under which the clock circuitry for the DDR-IO circuitry are configured such that the order of the clock circuitry by memory channel number skips a memory channel;

FIG. 7 is a schematic diagram of a fifth sub-channel solution employing a “Skip-2” configuration under which the clock circuitry for the DDR-IO circuitry are configured such that the order of the clock circuitry by memory channel number skips two memory channels;

FIG. 8 is a schematic diagram of a sixth sub-channel solution employing a “Skip-3” configuration under which the clock circuitry for the DDR-IO circuitry are configured such that the order of the clock circuitry by memory channel number skips three memory channels;

FIG. 9a is schematic diagram illustrating a first configuration of a system having an SoC coupled to multiple DRAM DIMMs wherein the subchannels and command clock signals for a memory channel are routed to the same DRAM DIMM;

FIG. 9b is a schematic diagram illustrating a second configuration of a system under which subchannels from separate memory channel IO interfaces are routed to the same DRAM DIMM employing a command-bus clock from one of the memory channel IO interfaces;

FIG. 9c is a schematic diagram illustrating a third configuration of a system employing two register clock driver chips, each provided with command-bus clock output from the IO interface of a respective memory channel; and

FIG. 9d is a schematic diagram illustrating a third configuration of a system that is a variant of the system of FIG. 9c employing two register clock driver chips that are provided with command-bus clock signals output from memory channel IO interfaces that are different than the memory channel IO interfaces used to provide the subchannel signals.

### DETAILED DESCRIPTION

Embodiments of methods and apparatus for Cross DRAM DIMM sub-channel pairing are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In the current art, System on a Chip (SOC) DRAM controllers and their associated Input-Output (IO) are stepped in the “y” dimension on the SOC dies. DIMMs are spaced horizontally, and each DIMM is connected to a specific DRAM channel controller. This requires a complicated swizzle of the signals leaving the controller IOs to line up with what is required by the DIMM.

In accordance with aspects of embodiments disclosed herein, each memory channel on a memory controller or System on a Chip with integrated memory controller(s) is segmented into two subchannels. In some embodiments the two subchannels are independent of each other except for sharing a command-bus clock. Some embodiments use an approach which uses one subchannel for two different memory channels instead of two subchannels from the same memory channel to supply the two subchannels per DIMM. This disclosure teaches two solutions to the shared command-bus clock on current DIMMs. One solution is to place an additional command-bus clock on the DIMM connector by repurposing existing MCR pins to provide a second command-bus clock to a second Registered Clock Driver (RCD) on the DIMM to allow the subchannels to be fully independent. Another solution is the pair every other DRAM controller IO to the same command-bus clock. Other solutions employ “skip” configurations under which a given IO interface uses a command-bus clock located proximate to a different IO interface. In some embodiments, other control pins, such as reset, will be treated as common between the two DIMMs and these signals will be routed on silicon to both controllers using the two DIMMs.

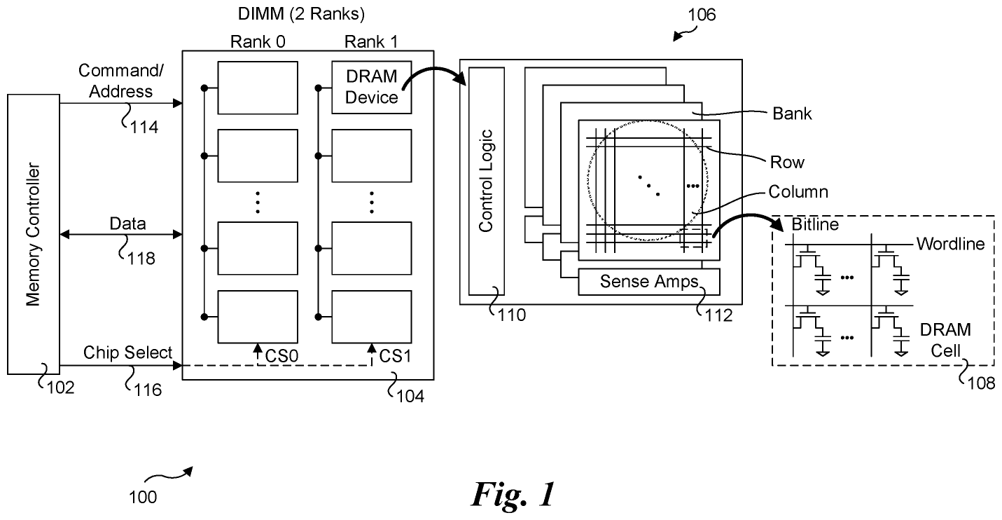

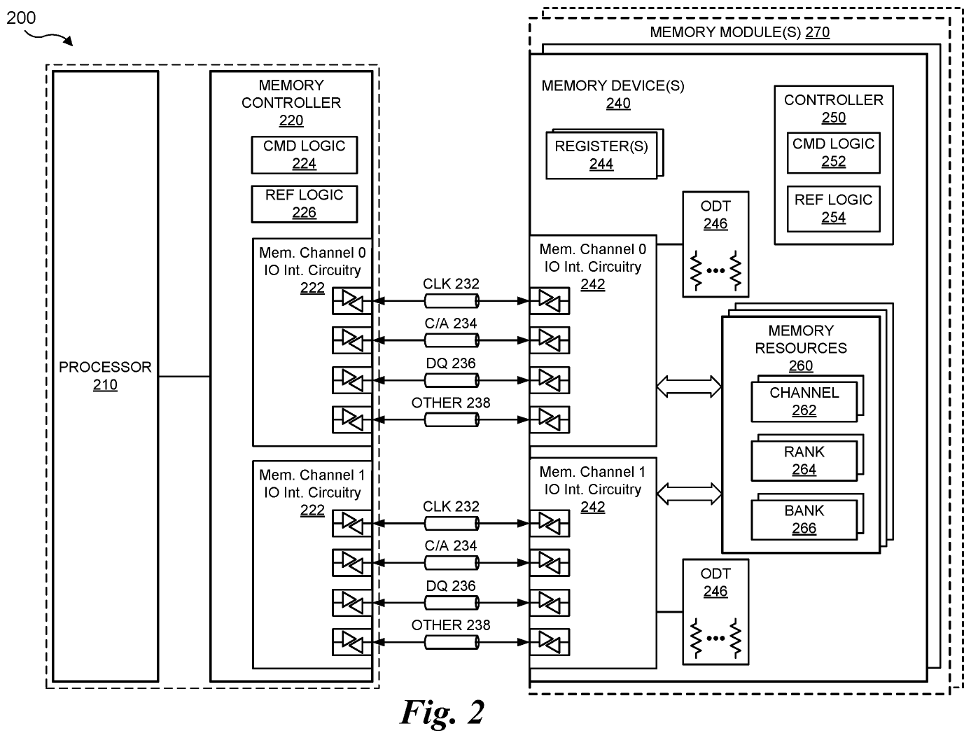

To better understand aspects of the teachings and principles of the embodiments disclosed herein, a brief primer on the operation of DRAM is provided with reference an exemplary memory subsystem illustrated in FIG. 1 and an exemplary system illustrated in FIG. 2. As shown in FIG. 1, selective elements of a memory subsystem 100 include a memory controller 102 coupled to a DIMM (Dual Inline Memory Module) 104 showing two ranks of DRAM devices 106. Generally, a DRAM DIMM may have one or more ranks. Each DRAM device includes a plurality of banks comprising an array of DRAM cells 108 that are organized (laid out) and as rows and columns. Each row comprises a Wordline (or wordline), while each column comprises a Bitline (or bitline). Each DRAM device 106 further includes control logic 110 and sense amps 112 that are used to access DRAM cells 108.

As further shown in FIG. 1, memory controller provides inputs comprising command/address 114 and chip select 116. For memory Writes, the memory controller inputs further include data 118 that are written to DRAM cells 108 based on the address and chip select inputs. Similarly, for memory Reads, data 118 stored in DRAM cells 108 identified by the address and chip select inputs is returned to memory controller 102.

As described herein, reference to memory devices (e.g., DRAM devices) can apply to different volatile memory types. Volatile memory is memory whose state (and therefore the data stored on it) is indeterminate if power is interrupted to the device. Dynamic volatile memory requires refreshing the data stored in the device to maintain state. One example of dynamic volatile memory includes DRAM, or some variant such as synchronous DRAM (SDRAM). A memory subsystem as described herein may be compatible with a number of memory technologies or standards, such as DDR3 (double data rate version 3, JESD79-3, originally published by JEDEC (Joint Electronic Device Engineering Council) on Jun. 27, 2007), DDR4 (DDR version 4, JESD79-4, originally published in September 2012 by JEDEC), LPDDR3 (low power DDR version 3, JESD209-3B, originally published in August 2013 by JEDEC), LPDDR4 (low power DDR version 4, JESD209-4, originally published by JEDEC in August 2014), WIO2 (Wide IO 2 (WideIO2), JESD229-2, originally published by JEDEC in August 2014), HBM (high bandwidth memory DRAM, JESD235, originally published by JEDEC in October 2013), LPDDR5 (originally published by JEDEC in February 2019, current version published in June 2021), HBM2 ((HBM version 2), originally published by JEDEC in December 2018), DDR5 (DDR version 5, originally published by JEDEC in July 2020), or others or combinations of memory technologies, and technologies based on derivatives or extensions of such specifications. In addition to the foregoing, the specification for LPDDR6 is currently being developed.

Under conventional (S)DRAM memory, data are generally accessed (Read and Written) using cachelines (also called cache lines) comprising a sequence of memory cells (bits) in a wordline. The cachelines for a given memory architecture generally have a predetermined width or size, such as 64 Bytes, noting other widths/sizes maybe used.

FIG. 2 illustrates an example system 200. In some examples, as shown in FIG. 2, system 200 includes a processor and elements of a memory subsystem in a computing device. Processor 210 represents a processing unit of a computing system that may execute an operating system (OS) and applications, which can collectively be referred to as the host or the user of the memory subsystem. The OS and applications execute operations that result in memory accesses. Processor 210 can include one or more separate processors. Each separate processor may include a single processing unit, a multicore processing unit, or a combination. The processing unit may be a primary processor such as a central processing unit (CPU), a peripheral processor such as a graphics processing unit (GPU), or a combination. Memory accesses may also be initiated by devices such as a network controller or hard disk controller. Such devices may be integrated with the processor in some systems or attached to the processer via a bus (e.g., a PCI express bus), or a combination. System 200 may be implemented as a system on a chip (SOC) or may be implemented with standalone components.

Reference to memory devices may apply to different memory types. Memory devices often refers to volatile memory technologies such as DRAM. In addition to, or alternatively to, volatile memory, in some examples, reference to memory devices can refer to a nonvolatile memory device whose state is determinate even if power is interrupted to the device. In one example, the nonvolatile memory device is a block addressable memory device, such as NAND or NOR technologies. A memory device may also include byte or block addressable types of non-volatile memory having a 3-dimensional (3-D) cross-point memory structure that includes, but is not limited to, chalcogenide phase change material (e.g., chalcogenide glass) hereinafter referred to as “3-D cross-point memory”. Non-volatile types of memory may also include other types of byte or block addressable non-volatile memory such as, but not limited to, multi-threshold level NAND flash memory, NOR flash memory, single or multi-level phase change memory (PCM), resistive memory, nanowire memory, ferroelectric transistor random access memory (FeTRAM), anti-ferroelectric memory, resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory, a magnetoresistive random access memory (MRAM) that incorporates memristor technology, spin transfer torque MRAM (STT-MRAM), or a combination of any of the above.

Descriptions herein referring to a “RAM” or “RAM device” can apply to any memory device that allows random access, whether volatile or nonvolatile. Descriptions referring to a “DRAM”, “SDRAM, “DRAM device” or “SDRAM device” may refer to a volatile random access memory device. The memory device, SDRAM or DRAM may refer to the die itself, to a packaged memory product that includes one or more dies, or both. In some examples, a system with volatile memory that needs to be refreshed may also include at least some nonvolatile memory.

Memory controller 220, as shown in FIG. 2, may represent one or more memory controller circuits or devices for system 200. Also, memory controller 220 may include logic and/or features that generate memory access commands in response to the execution of operations by processor 210. In some examples, memory controller 220 may access one or more memory device(s) 240. For these examples, memory device(s) 240 may be SDRAM or DRAM devices in accordance with any referred to above. Memory device(s) 240 may be organized and managed through different channels, where these channels may couple in parallel to multiple memory devices via buses and signal lines. Each channel may be independently operable. Thus, separate channels may be independently accessed and controlled, and the timing, data transfer, command and address exchanges, and other operations may be separate for each channel. Coupling may refer to an electrical coupling, communicative coupling, physical coupling, or a combination of these. Physical coupling may include direct contact. Electrical coupling, for example, includes an interface or interconnection that allows electrical flow between components, or allows signaling between components, or both. Communicative coupling, for example, includes connections, including wired or wireless, that enable components to exchange data.

According to some examples, settings for each channel are controlled by separate mode registers or other register settings. For these examples, memory controller 220 may manage a separate memory channel, although system 200 may be configured to have multiple channels managed by a single memory controller, or to have multiple memory controllers on a single channel. In one example, memory controller 220 is part of processor 210, such as logic and/or features of memory controller 220 are implemented on the same die or implemented in the same package space as processor 210, sometimes referred to as an integrated memory controller.

Memory controller 220 includes Input/Output (IO) interface circuitry 222 to couple to a memory bus, which is replicated for two memory channels 0 and 1. IO interface circuitry 222 (as well as IO interface circuitry 242 of memory device(s) 240) may include pins, pads, connectors, signal lines, traces, or wires, or other hardware to connect the devices, or a combination of these. IO interface circuitry 222 may include a hardware interface. As shown in FIG. 2, IO interface circuitry 222 includes at least drivers/transceivers for signal lines. Commonly, wires within an integrated circuit interface couple with a pad, pin, or connector to interface signal lines or traces or other wires between devices. IO interface circuitry 222 can include drivers, receivers, transceivers, or termination, or other circuitry or combinations of circuitry to exchange signals on the signal lines between memory controller 220 and memory device(s) 240. The exchange of signals includes at least one of transmit or receive. While shown as coupling IO interface circuitry 222 from memory controller 220 to IO interface circuitry 242 of memory device(s) 240, it will be understood that in an implementation of system 200 where groups of memory device(s) 240 are accessed in parallel, multiple memory devices can include IO interface circuitry to the same interface of memory controller 220. In an implementation of system 200 including one or more memory module(s) 270, IO interface circuitry 242 may include interface hardware of memory module(s) 270 in addition to interface hardware for memory device(s) 240. Other memory controllers 220 may include multiple, separate interfaces to one or more memory devices of memory device(s) 240.

In some examples, memory controller 220 may be coupled with memory device(s) 240 via multiple signal lines. The multiple signal lines may include at least a clock (CLK) 232, command/address (C/A) 234, and write data (DQ) and read data (DQ) 236, and zero or more other signal lines 238. According to some examples, a composition of signal lines coupling memory controller 220 to memory device(s) 240 may be referred to collectively as a memory bus. The signal lines for C/A 234 may be referred to as a “command bus”, a “C/A bus” or a CMD/ADD bus, or some other designation indicating the transfer of commands and/or address data. The signal lines for DQ 236 may be referred to as a “data bus”.

According to some examples, independent channels may have different clock signals, command buses, data buses, and other signal lines. For these examples, system 200 may be considered to have multiple “buses,” in the sense that an independent interface path may be considered a separate bus. It will be understood that in addition to the signal lines shown in FIG. 2, a bus may also include at least one of strobe signaling lines, alert lines, auxiliary lines, or other signal lines, or a combination of these additional signal lines. It will also be understood that serial bus technologies can be used for transmitting signals between memory controller 220 and memory device(s) 240. An example of a serial bus technology is 8B10B encoding and transmission of high-speed data with embedded clock over a single differential pair of signals in each direction. In some examples, C/A 234 represents signal lines shared in parallel with multiple memory device(s) 240. In other examples, multiple memory devices share encoding command signal lines of C/A 234, and each has a separate chip select (CS_n) signal line to select individual memory device(s) 240.

In some examples, the bus between memory controller 220 and memory device(s) 240 includes a subsidiary command bus routed via signal lines included in C/A 234 and a subsidiary data bus to carry the write and read data routed via signal lines included in DQ 236. In some examples, C/A 234 and DQ 236 may separately include bidirectional lines. In other examples, DQ 236 may include unidirectional write signal lines to write data from the host to memory and unidirectional lines to read data from the memory to the host.

According to some examples, in accordance with a chosen memory technology and system design, signals lines included in other 238 may augment a memory bus or subsidiary bus. For example, strobe line signal lines for a DQS. Based on a design of system 200, or memory technology implementation, a memory bus may have more or less bandwidth per memory device included in memory device(s) 240. The memory bus may support memory devices included in memory device(s) 240 that have either a x32 interface, a x16 interface, a x8 interface, or other interface. The convention “xW,” where W is an integer that refers to an interface size or width of the interface of memory device(s) 240, which represents a number of signal lines to exchange data with memory controller 220. The interface size of these memory devices may be a controlling factor on how many memory devices may be used concurrently per channel in system 200 or coupled in parallel to the same signal lines. In some examples, high bandwidth memory devices, wide interface memory devices, or stacked memory devices, or combinations, may enable wider interfaces, such as a x128 interface, a x256 interface, a x512 interface, a x1024 interface, or other data bus interface width.

According to some examples, memory device(s) 240 represent memory resources for system 200. For these examples, each memory device included in memory device(s) 240 is a separate memory die. Separate memory devices may interface with multiple (e.g., 2) channels per device or die. A given memory device of memory device(s) 240 may include IO interface circuitry 242 and may have a bandwidth determined by an interface width associated with an implementation or configuration of the given memory device (e.g., x16 or x8 or some other interface bandwidth). IO interface circuitry 242 may enable the memory devices to interface with memory controller 220. IO interface circuitry 242 may include a hardware interface and operate in coordination with IO interface circuitry 222 of memory controller 220.

In some examples, multiple memory device(s) 240 may be connected in parallel to the same command and data buses (e.g., via C/A 234 and DQ 236). In other examples, multiple memory device(s) 240 may be connected in parallel to the same command bus but connected to different data buses. For example, system 200 may be configured with multiple memory device(s) 240 coupled in parallel, with each memory device responding to a command, and accessing memory resources 260 internal to each memory device. For a write operation, an individual memory device of memory device(s) 240 may write a portion of the overall data word, and for a read operation, the individual memory device may fetch a portion of the overall data word. As non-limiting examples, a specific memory device may provide or receive, respectively, 8 bits of a 128-bit data word for a read or write operation, or 8 bits or 16 bits (depending for a x8 or a x16 device) of a 256-bit data word. The remaining bits of the word may be provided or received by other memory devices in parallel.

According to some examples, memory device(s) 240 may be disposed directly on a motherboard or host system platform (e.g., a PCB (printed circuit board) on which processor 210 is disposed) of a computing device. Memory device(s) 240 may be organized into memory module(s) 270. In some examples, memory module(s) 270 may represent dual inline memory modules (DIMMs). In some examples, memory module(s) 270 may represent other organizations or configurations of multiple memory devices that share at least a portion of access or control circuitry, which can be a separate circuit, a separate device, or a separate board from the host system platform. In some examples, memory module(s) 270 may include multiple memory device(s) 240, and memory module(s) 270 may include support for multiple separate channels to the included memory device(s) 240 disposed on them.

In some examples, memory device(s) 240 may be incorporated into a same package as memory controller 220. For example, incorporated in a multi-chip-module (MCM), a package-on-package with through-silicon via (TSV), or other techniques or combinations. Similarly, in some examples, memory device(s) 240 may be incorporated into memory module(s) 270, which themselves may be incorporated into the same package as memory controller 220. It will be appreciated that for these and other examples, memory controller 220 may be part of or integrated with processor 210.

As shown in FIG. 2, in some examples, memory device(s) 240 include memory resources 260. Memory resources 260 may represent individual arrays of memory locations or storage locations for data. Memory resources 260 may be managed as rows of data, accessed via wordline (rows) and bitline (individual bits within a row) control. Memory resources 260 may be organized as separate channels 262, ranks 264, and banks of memory 266. Channels may refer to independent control paths to storage locations within memory device(s) 240. Ranks may refer to common locations across multiple memory devices (e.g., same row addresses within different memory devices). Banks may refer to arrays of memory locations within a given memory device of memory device(s) 240. Banks may be divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to access memory resources 260. For example, the same physical memory locations can be accessed over a specific channel as a specific bank, which can also belong to a rank. Thus, the organization of memory resources 260 may be understood in an inclusive, rather than exclusive, manner.

According to some examples, as shown in FIG. 2, memory device(s) 240 include one or more register(s) 244. Register(s) 244 may represent one or more storage devices or storage locations that provide configuration or settings for operation memory device(s) 240. In one example, register(s) 244 may provide a storage location for memory device(s) 240 to store data for access by memory controller 220 as part of a control or management operation. For example, register(s) 244 may include one or more mode registers (MRs) and/or may include one or more multipurpose registers.

In some examples, writing to or programming one or more registers of register(s) 244 may configure memory device(s) 240 to operate in different “modes”. For these examples, command information written to or programmed to the one or more register may trigger different modes within memory device(s) 240. Additionally, or in the alternative, different modes can also trigger different operations from address information or other signal lines depending on the triggered mode. Programmed settings of register(s) 244 may indicate or trigger configuration of IO settings. For example, configuration of timing, termination, on-die termination (ODT), driver configuration, or other IO settings.

According to some examples, memory device(s) 240 includes ODT 246 as part of the interface hardware associated with IO interface circuitry 242. ODT 246 may provide settings for impedance to be applied to the interface to specified signal lines. For example, ODT 246 may be configured to apply impedance to signal lines include in DQ 236 or C/A 234. The ODT settings for ODT 246 may be changed based on whether a memory device of memory device(s) 240 is a selected target of an access operation or a non-target memory device. ODT settings for ODT 246 may affect timing and reflections of signaling on terminated signal lines included in, for example, C/A 234 or DQ 236. Control over ODT setting for ODT 246 can enable higher-speed operation with improved matching of applied impedance and loading. Impedance and loading may be applied to specific signal lines of IO interface circuitry 242, 222 (e.g., C/A 234 and DQ 236) and is not necessarily applied to all signal lines.

In some examples, as shown in FIG. 2, memory device(s) 240 includes controller 250. Controller 250 may represent control logic within memory device(s) 240 to control internal operations within memory device(s) 240. For example, controller 250 decodes commands sent by memory controller 220 and generates internal operations to execute or satisfy the commands. Controller 250 may be referred to as an internal controller and is separate from memory controller 220 of the host. Controller 250 may include logic and/or features to determine what mode is selected based on programmed or default settings indicated in register(s) 244 and configure the internal execution of operations for access to memory resources 260 or other operations based on the selected mode. Controller 250 generates control signals to control the routing of bits within memory device(s) 240 to provide a proper interface for the selected mode and direct a command to the proper memory locations or addresses of memory resources 260. Controller 250 includes command (CMD) logic 252, which can decode command encoding received on command and address signal lines. Thus, CMD logic 252 can be or include a command decoder. With command logic 252, memory device can identify commands and generate internal operations to execute requested commands.

Referring again to memory controller 220, memory controller 220 includes CMD logic 224, which represents logic and/or features to generate commands to send to memory device(s) 240. The generation of the commands can refer to the command prior to scheduling, or the preparation of queued commands ready to be sent. Generally, the signaling in memory subsystems includes address information within or accompanying the command to indicate or select one or more memory locations where memory device(s) 240 should execute the command. In response to scheduling of transactions for memory device(s) 240, memory controller 220 can issue commands via IO interface circuitry 222 to cause memory device(s) 240 to execute the commands. In some examples, controller 250 of memory device(s) 240 receives and decodes command and address information received via IO interface circuitry 242 from memory controller 220. Based on the received command and address information, controller 250 may control the timing of operations of the logic, features and/or circuitry within memory device(s) 240 to execute the commands. Controller 250 may be arranged to operate in compliance with standards or specifications such as timing and signaling requirements for memory device(s) 240. Memory controller 220 may implement compliance with standards or specifications by access scheduling and control.

In some examples, memory controller 220 includes refresh (REF) logic 226. REF logic 226 may be used for memory resources that are volatile and need to be refreshed to retain a deterministic state. REF logic 226, for example, may indicate a location for refresh, and a type of refresh to perform. REF logic 226 may trigger self-refresh within memory device(s) 240 or execute external refreshes which can be referred to as auto refresh commands by sending refresh commands, or a combination. According to some examples, system 200 supports all bank refreshes as well as per bank refreshes. All bank refreshes cause the refreshing of banks within all memory device(s) 240 coupled in parallel. Per bank refreshes cause the refreshing of a specified bank within a specified memory device of memory device(s) 240. In some examples, controller 250 within memory device(s) 240 includes a REF logic 254 to apply refresh within memory device(s) 240. REF logic 254, for example, may generate internal operations to perform refresh in accordance with an external refresh received from memory controller 220. REF logic 254 may determine if a refresh is directed to memory device(s) 240 and determine what memory resources 260 to refresh in response to the command.

### Subchannel Architectures

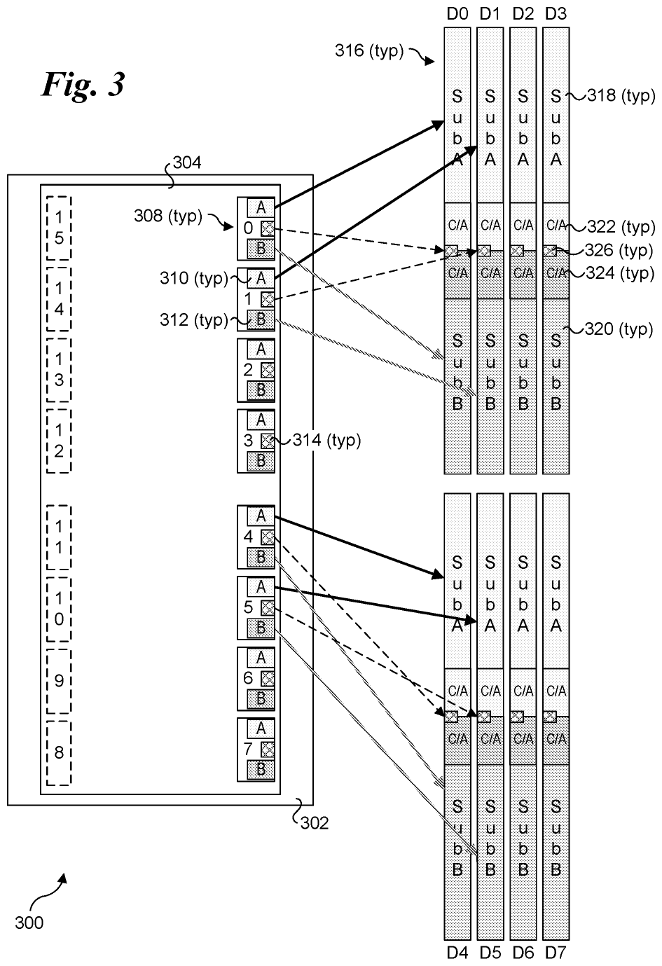

FIG. 3 shows a first system architecture 300 including an SoC 302 with a die 304 with 16 memory channels 308 including 8 optional memory channels (shown in dashed outline). The memory channels are also numbered 0-15. Each memory channel includes IO circuitry comprising sets of signal lines to support a pair of subchannel 310 and 312 (also labeled ‘A’ and ‘B’) and a clock signal 314. System architecture 300 further includes eight DIMMs 316 (also labeled D0, D1, D2, D3, D4, D5, D6, and D7 in the Figures herein). Each DIMM 316 includes memory channel IO interface circuitry divided into a pair of subchannels 318 and 320 (also labeled and referred to as sub(channel) ‘A’ and sub(channel) ‘B’, which respectively include a set of C/A signals 322 and 324. Each DIMM 316 further includes a single RCD input 326.

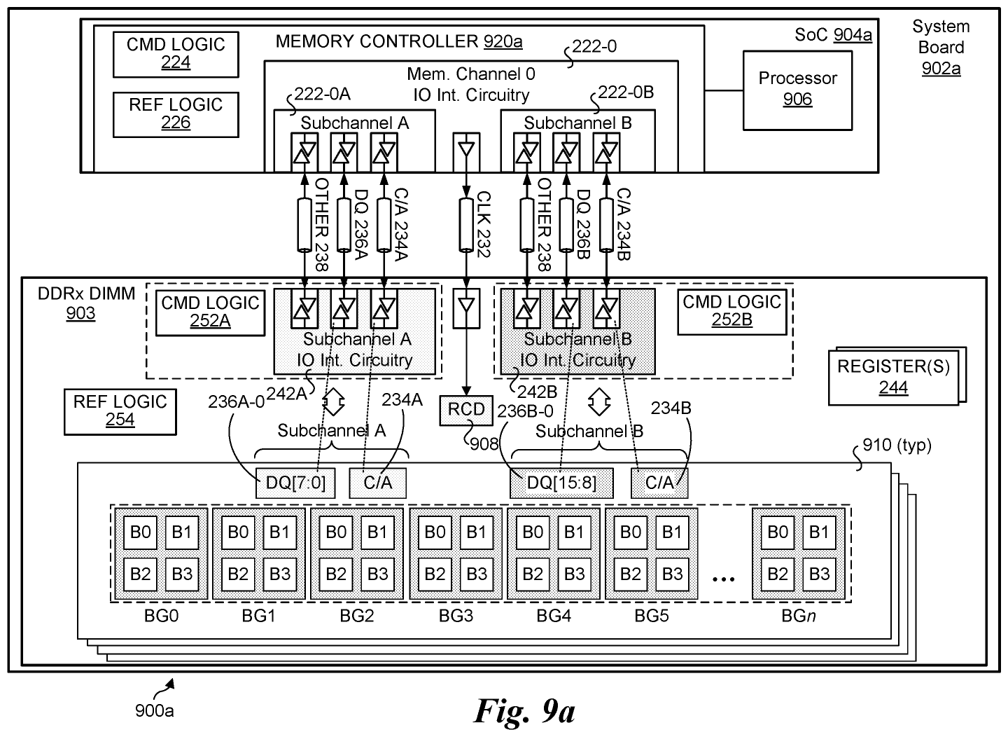

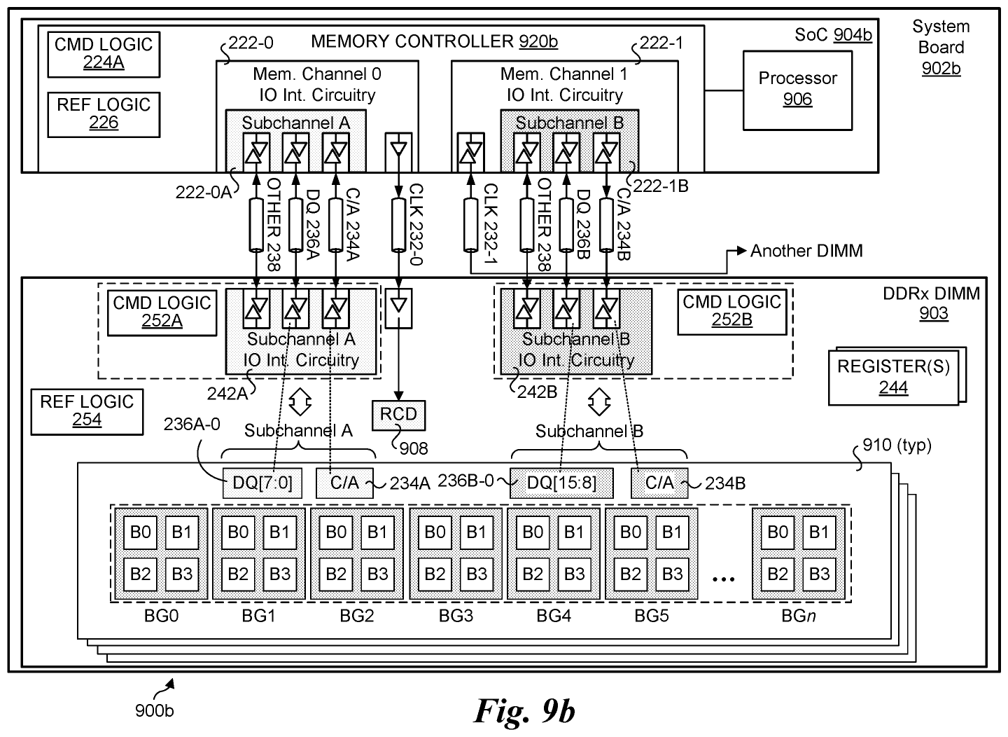

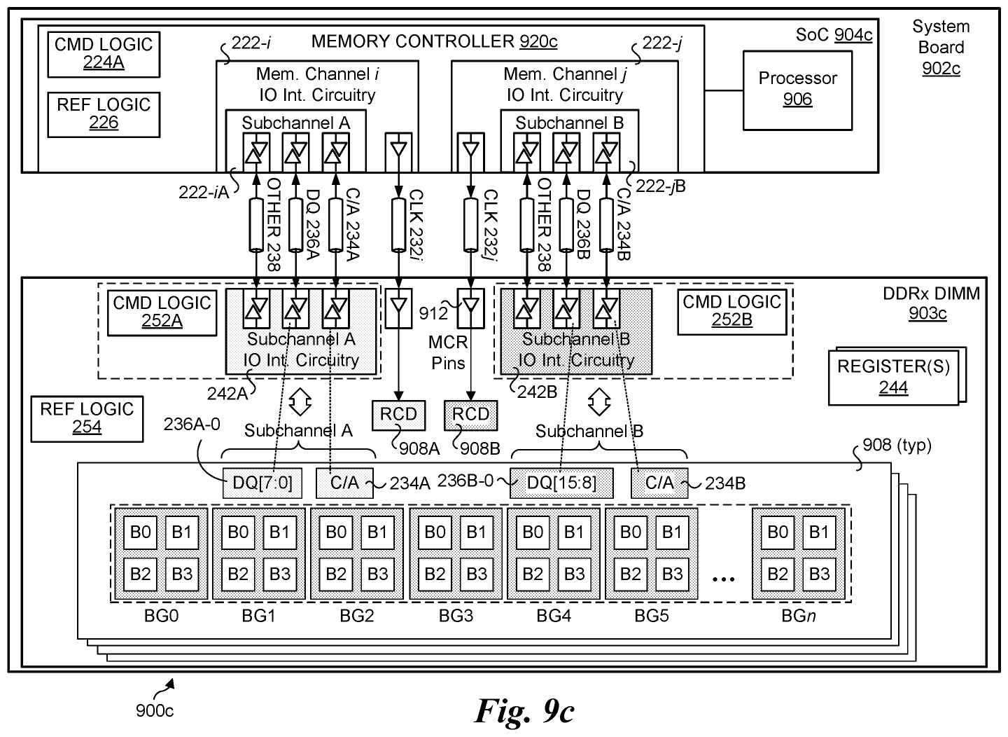

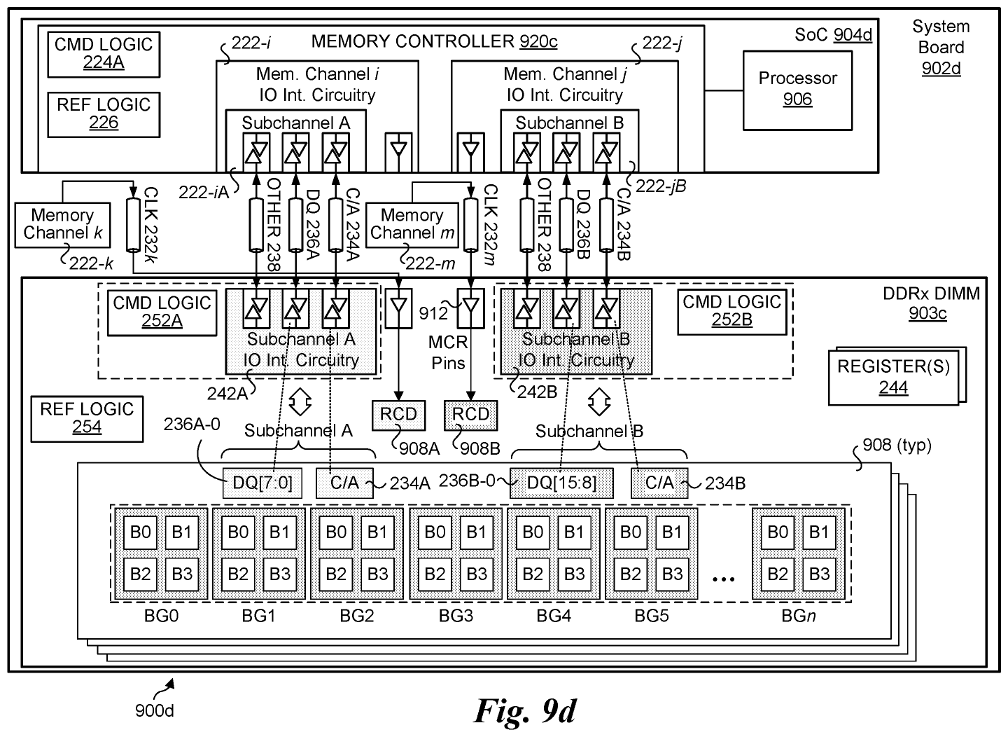

Under this first solution, for a given memory channel 308, IO signals corresponding to subchannel A are coupled to corresponding IO signals received by a subchannel A on a DIMM 316 via wiring in a printed circuit board (PCB) or other substrate (not shown), while IO signals corresponding to subchannel B are coupled to corresponding IO signals received by a subchannel B on the DIMM via wiring in the PCB or other substrate. Thus, signals from IO memory channel 0 are coupled to DIMM D0, IO channel 1 are coupled to DIMM D1, memory channel 4 are coupled to DIMM D4, IO channel 5 are coupled to DIMM D5. This pattern would also pertain to the other memory channels 2, 3, 6, and 7, and DIMMs D2, D3, D6 and D7. For simplicity and clarity, the double-ended arrows are shown as being connected somewhere within the regions labeled ‘SubA’ or ‘SubB’ in the Figures herein. This would include CMD and Address signals, as well as other signals commonly used for DDR (double data rate) memory channels (e.g., DQ and DQS, for example—see FIGS. 9a-9d below for further details).

System architecture 300 provides the advantages of reducing swizzle in signal routing and reducing the package and board costs.

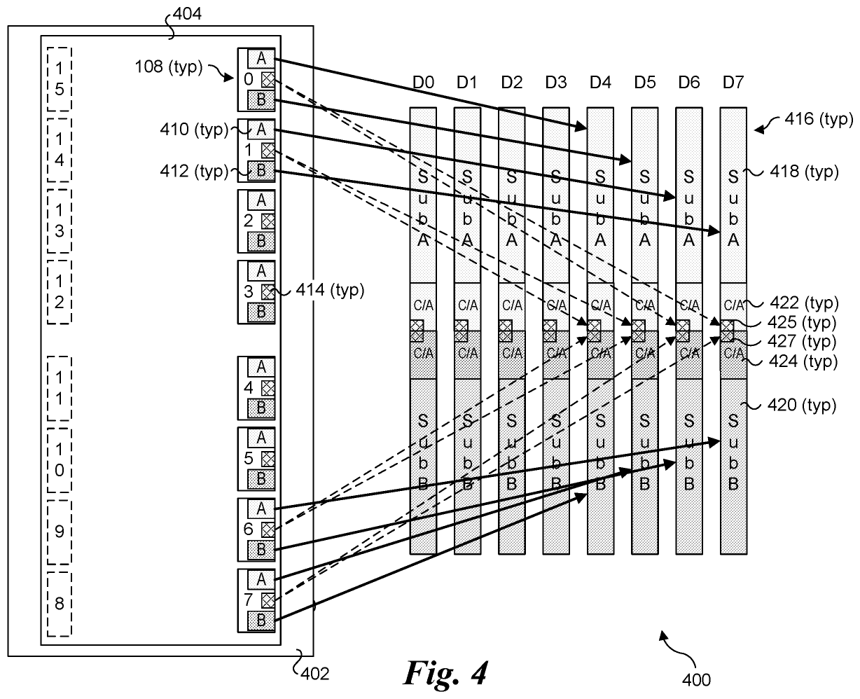

FIG. 4 shows a system architecture 400 including an SoC 402 with a die 404 employing a second sub-channel based DIMM layout. Under this solution, each CMD subchannel on DIMMs 416 receives a separate clock signal from the memory IO interface circuitry on SoC 102. As further shown, each DIMM 416 includes memory channel IO interface circuitry divided into a pair of subchannels 418 and 420 (also labeled and referred to as sub(channel) ‘A’ and sub(channel) ‘B’), which respectively include a set of C/A signals 422 and 424. C/A signals 422 are used with a respective RDC input 425, while C/A signals 424 are used with a respective RDC input 427.

As further shown, the clock output signal for IO channel 0 is coupled to RCD inputs 425 on each of DIMMs D6 and D7, the clock output signal for IO channel 1 is coupled to RCD inputs 425 on each of DIMMs D4 and D5, the clock output signal for IO channel 6 is coupled to RCD inputs 427 on each of DIMMs D4 and D5, and the clock output signal for IO channel 7 is coupled to RCD inputs 427 on each of DIMMs D6 and D7. As before, only a portion of the signals are shown in FIG. 4. One having skill in the art will recognize a similar pattern would be used for IO channels 2, 3, 4, and 5, and DIMMs D0, D1, D2, and D3.

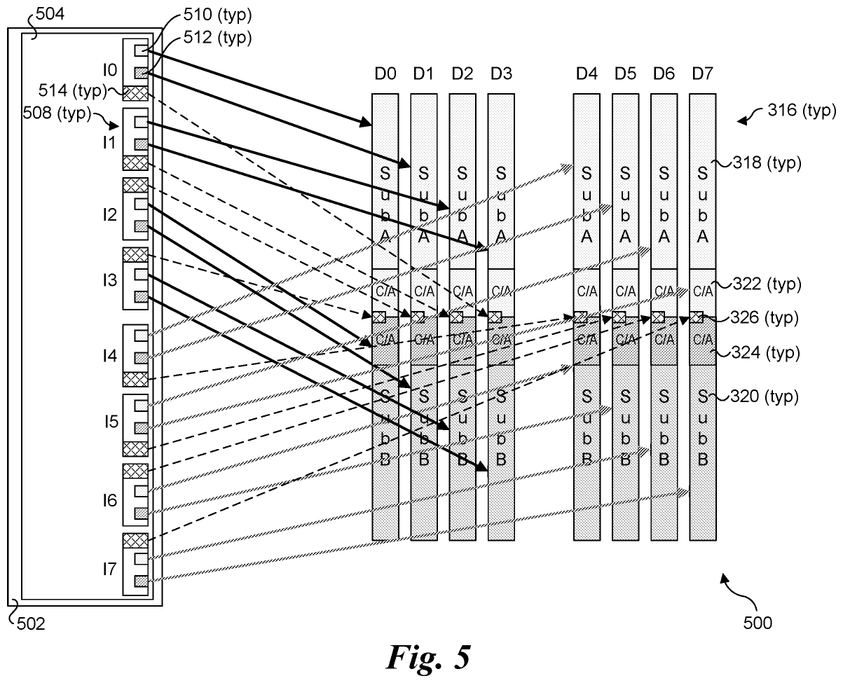

FIG. 5 shows a system architecture 500 using a subchannel based DIMM layout according to a third embodiment. An SoC 502 includes a die 504 having eight sets of DDR-IO blocks 508 (also labeled I0, I1, I2, I3, I4, I5, I6, I7, and I8). The DDR-IO blocks include circuitry for generating outbound DDR IO signals send to DIMMs 316 and for processing DDR IO signals received from DIMMs 316. For simplicity, the circuitry is depicted as including C/A subchannel ‘A’ and ‘B’ interfaces 510 and 512 and a clock 514.

As shown, the C/A sub-channel signals and clock signals for each of DDR IO blocks I0, I1, I2, and I3 are coupled to different DIMMs D0, D1, D2, and D3. For example, for DDR IO block I0, C/A signals and data lines for subchannel 510 are coupled to mating interfaces on DIMM D0, while the C/A signals and data lines for subchannel 512 are coupled to mating interfaces on DIMM D1, and clock signal 514 is provided to the RCD input 326 on DIMM D3. Similarly, the C/A sub-channel signals and clock signals for each of DDR IO blocks I4, I5, I6, and I7 are coupled to different DIMMs D4, D5, D6, and D7.

Under this configuration there is a pair of adjacent clocks for every other DDR-IO block instance. For example, the clocks for DDR-IO blocks I1 and I2 are adjacent, as are the clocks for DDR-IO blocks I5 and I6. System architecture 500 also can be used with existing DDRx DIMMs.

System architecture 600 shows a subchannel based DIMM configuration employing a “Skip 1” scheme under which clocks for a given DDR-IO block are configured to be logically adjacent to another DDR-IO block rather than being logically co-located with the DDR-IO block. As shown, system 600 includes an SoC 602 having a die 604 die including either sets of DDR-IO circuitry depicted as a DDR-IO block 608, a clock 610, and an IO interface 612 including a pair of subchannels 614 and 616. The DDR-IO blocks 608 are also labeled I0, I1, I2, I3, I4, I5, I6, I7, and I8, while each of the clocks 610 and IO interfaces 612 are labeled 0, 1, 2, 3, 4, 5, 6, 7, and 8.

As shown, each DDR-IO block 608 is disposed adjacent to a respective IO interface 612 with the same number, e.g., DDR-IO block I0 is adjacent to IO interface 0, DDR-IO block I1 is adjacent to IO interface 1, etc. Meanwhile, clocks 1, 2, 5, and 6 are moved such that the vertical arrangement of the clock is 0, 2, 1, 3, 4, 6, 5, and 7. In this configuration, there is a skip of 1 in the number of vertically adjacent pairs of clocks, e.g., clocks 0-2, 1-3, 4-6, and 5-7, hence the name “Skip-1.”

Under system architecture 600, for IO interfaces 0, 3, 4, and 7, the clock signal associated with the DDR-IO circuitry instance and one of the subchannels are routed to the same DIMM (respectively DIMM D3 (subchannel B), DIMM D0 (subchannel B), DIMM D6 (subchannel A), and DIMM D5 (subchannel A). However, this is not the case for IO interfaces 1, 2, 5, and 6—for a given DIMM 316 the C/A signals for subchannel A and subchannel B and the clock signal originate from different DDR-IO circuitry instances.

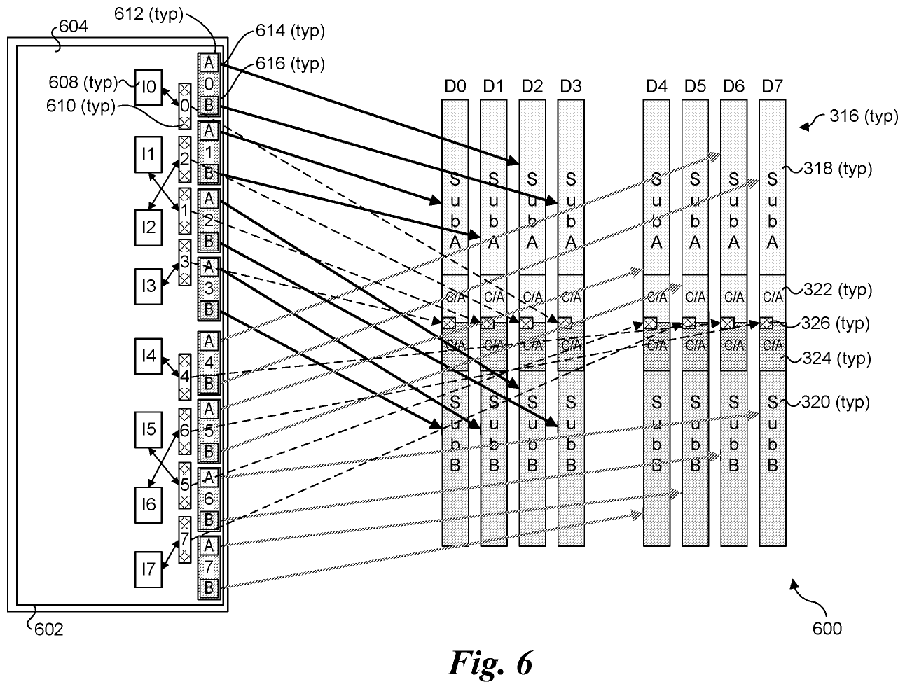

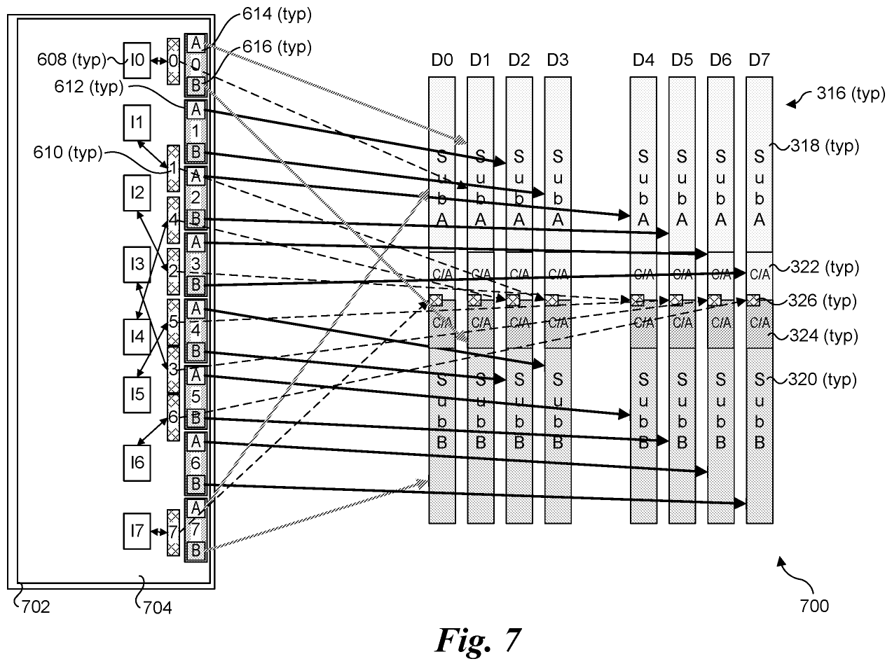

System architecture 700 shows a subchannel based DIMM configuration employing a “Skip 2” scheme and including an Soc 702 with a die 704 having eight instances of DDR-IO circuitry corresponding to respective memory channels. As depicted by like-numbered blocks and components in FIGS. 6 and 7, the blocks and components in architectures 600 and 700 are similar. The difference is the vertical arrangement of the clocks. Under the Skip 2 scheme, vertically logically adjacent clocks for the inner 6 clocks 1-6 skip 2 numbers on a pairwise basis: 1-4, 2-5, and 3-6, hence the name. Under system architecture 700, for IO interfaces 0 and 7, the clock signal associated with the DDR-IO circuitry instance both subchannels are routed to the same DIMM (respectively DIMMs D1 and D0). Meanwhile, for each of IO interfaces 1-6 one of the subchannels and the clock are routed to the same DIMM: DIMM D3 (subchannel B) for IO interface 1; DIMM D4 (subchannel A) for IO interface 2; DIMM D6 (subchannel A) for IO interface 3; DIMM D2 (subchannel B) for IO interface 4; DIMM D5 (subchannel B) for IO interface 5; and DIMM D7 (subchannel B) for IO interface 6.

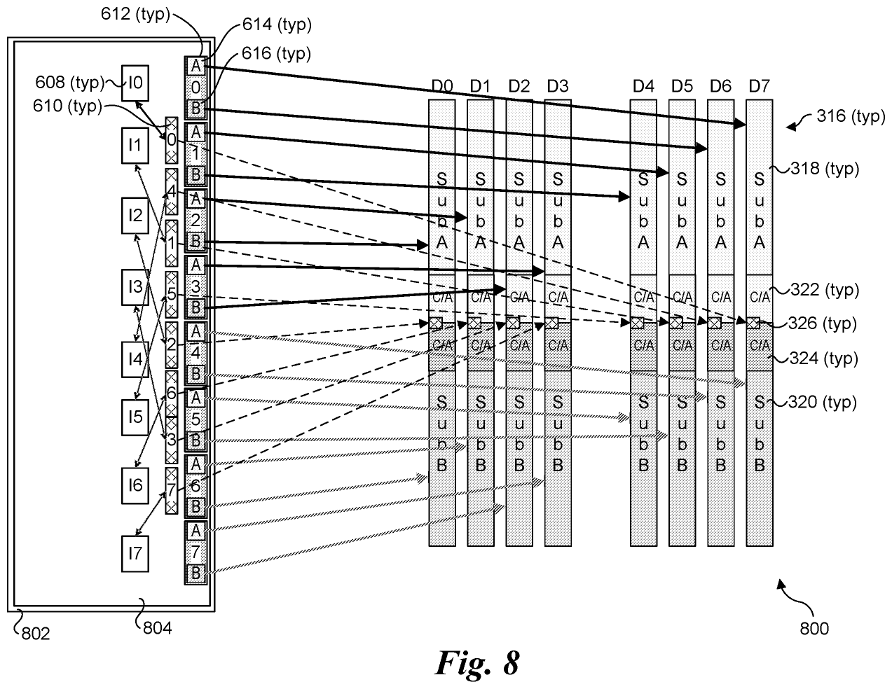

System architecture 800 shows a subchannel based DIMM configuration employing a “Skip 3” scheme and including an Soc 802 with a die 804 having eight instances of DDR-IO circuitry corresponding to respective memory channels. As depicted by like-numbered blocks and components in FIGS. 6, 7, and 8, the blocks and components in architectures 600, 700, and 800 are similar. The difference, again, is the vertical arrangement of the clocks. Under the Skip 3 scheme, vertically adjacent clocks skip 3 numbers on a pairwise basis: 0-4, 1-5, 2-6, and 3-7, hence the name. This configuration enables the clock signal and the signals for one of the subchannels for each of IO interfaces 0-7 to be routed to the same DIMM, as follows: DIMM D7 (subchannel A) for IO interface 0; DIMM D5 (subchannel A) for IO interface 1; DIMM D0 (subchannel B) for IO interface 2; DIMM D2 (subchannel B) for IO interface 3; DIMM D6 (subchannel B) for IO interface 4, DIMM D4 (subchannel A) for IO interface 5, and DIMM D1 (subchannel A) for IO interface 6; and DIMM D3 (subchannel A) for IO interface 7.

Systems 900a, 900b, 900c, and 900d in FIGS. 9a, 9b, 9c, and 9d show further details of the circuitry and components implemented in system architectures illustrated and describe above. System 900a includes a system board 902a to which an SoC 904a and multiple DDRx DIMMs 903 are mounted (e.g., installed in a DIMM slot or otherwise operatively coupled to system board 902). The ‘x’ for DDRx is representative of the generation of the DDR specification implemented by the DIMM—for example, DDRS for fifth generation. For illustrative purposes, a single DDRx DIMM 903 is shown in FIGS. 9a, 9b, 9c, and 9d.

SoC 904 includes a processor 906 and an integrated memory controller 920a including CMD logic 224 and REF logic 226. Memory controller 920a includes IO interface circuitry for multiple memory channels of which a single instance is shown; it will be understood that there would be multiple similar instances. In this example, the IO interface circuitry for a memory channel 0 is partitioned into a pair of subchannels 222-0A and 222-0B (e.g., subchannels A and B), each providing respective C/A signals 232A and 232B, respective data lines DQ 236A and 236B, and option other signals 238. The memory channel 0 IO circuitry further includes a clock signal 232 that is shared by both subchannels 222-0A and 222-0B. interface circuitry 222-0 and 222-1 for memory channels 0 and 1.

In this example, the memory channel interface circuitry 242A and 242B on DDRx DIMM 903 for each subchannel employs a DQ bus width of approximately 40 bits. Each subchannel on the DIMM includes a respective CMD logic block 252A and 252B, which the DIMM also includes REF logic 254 and registers 244. Clock signal 232 is received at by an RCD chip 908, which is used to provide clock signals for the components on the DIMM, including multiple DRAM devices (e.g., chips or packages) 910. Internally, sets of DQ data lines and C/A signals received at the pins of DDRx DIMM 903 are routed to DQ data lines and C/A signals for each DRAM device 910. As shown, the DQ data lines on each DRAM device 910 are split into a pair of subchannels A and B, with the lower 8 bits (DQ[7:0], 236A-0) used for subchannel A and the upper 8 bits (DQ[15:8], 236B-0) used for subchannel B. The use of ‘−0’ here means this is the portion of the subchannel A and B DQ data lines that are routed to a first DRAM device 910. The other DRAM devices would have a similar configuration, but would be coupled to different subsets of the DQ lines coupled to the IO interface circuitry of the DIMM. As further shown, the memory in DRAM device 910 is organized as n bank groups BG0, BG1 . . . BGn, each having four banks B0, B1, B2, and B3. However, this is merely illustrative and non-limiting, as the internal organization of the memory resources for a DRAM device may vary and is outside the scope of this disclosure.

System 900a is illustrative of the memory subchannel A and B and DIMM connections shown in system architecture 300 in FIG. 3, where the IO interface signals and data lines for subchannels A and B and the clock signal for a given memory channel interface with the same DIMM 316. In some embodiments, this system architecture may be implemented with to existing DDRx DIMMs, such as but not limited to DDR5 DIMMs.

System 900b in FIG. 9b includes a system board 902b to which an SoC 904b and multiple DDRx DIMMs 903 are mounted/operatively coupled. In this example, the DDRx DIMMs 903 are the same as in system 900a. However, the difference is where the subchannel C/A signals, clock signal and data lines for the subchannels originate. Memory controller 920b shows IO interface circuitry 222-0 and 222-1 for a pair of memory channels 0 and 1, with IO interface circuitry 222-0A for subchannel A of memory channel 0 providing the subchannel A C/A signals 234A and DQ data lines 236A, while IO interface circuitry 222-1B for subchannel B of memory channel 1 providing the subchannel B C/A signals 234B and DQ data lines 236B. In this example, the clock signal 232-0 from memory channel IO interface circuitry 222-0 provides the input clock signal to RCD chip 908. Meanwhile, the clock signal 232-1 for memory channel 1 IO interface circuitry used for the RCD input for another DIMM (not shown).

The configuration shown for system 900b corresponds to routing instances in the Skip-1, Skip-2, and Skip-3 examples where signals and data lines one of the subchannels and the clock for a given DDR-IO instance are routed to the same DIMM 316, while the signals and data lines for the other subchannel comes from a different DDR-IO instance.

System 900c in FIG. 9c includes a system board 902c to which an SoC 904c and multiple DDRx DIMMs 903c are mounted/operatively coupled. DDRx DIMM 903c include a pair of RCD chips 908A and 908B for respective subchannels A and B. Memory controller 920c has multiple instances of IO interface circuitry for multiple memory channels, including IO interface circuitry 222-i for a memory channel i, and IO interface circuitry 222-j for a memory channel j, where i and j are representative of memory channel numbers (e.g., 0-7 in the preceding examples).

IO interface circuitry 222-iA for subchannel A of memory channel i provides the C/A signals 234A and DQ data lines 236A for subchannel A of DDRx DIMM 903c, while IO interface circuitry 222-jB for subchannel B of memory channel j provides the C/A signals 234B and DQ data lines 236B for subchannel B of DDRx DIMM 903c. Clock signal 232i for memory channel i and clock signal 232j for memory channel j are respectively received as clock input to RCD chips 908A and 908B. In one embodiment, MCR pins 912 on the DIMM connector are repurposed and used to provide one of the clock inputs to the RCD chips (clock signal 232j is provided to RCD chip 908B using MCR pins 912 in the illustrated example). When using separate clocks for each of subchannels A and B the subchannels are enabled to operate independent of one another, since they each employ their own clock.

System 900d of FIG. 9d is a variant of system 900c and includes a system board 902d to which an SoC 904d and multiple DDRx DIMMs 903c are mounted/operatively coupled. The difference here is the clock signals received by RCD chips 908A and 908B originate from IO interface circuitry 222-k for a memory k and IO interface circuitry 222-m for a memory channel m. In a manner similar to above, the letters i, j, k, and m are representative of different memory channels (or DDR-IO interface circuitry) in the foregoing examples.

The foregoing examples shown signals for a subchannel A on the memory controller being coupled to IO interface circuitry for subchannel A on the DIMMSs and signals for a subchannel B on the memory controller being coupled to IO interface circuitry for subchannel B on the DIMMs. This is for illustrative purposes, wherein the label ‘A’ or ‘B’ on the memory controller side represents one of the two subchannels for a given memory channel. For example, as illustrated in some of the previous diagrams, a given DIMM may be coupled to a pair of subchannels A or a pair of subchannels B on the memory controller side.

While various embodiments described herein use the term System-on-a-Chip or System-on-Chip (“SoC”) to describe a device or system having a processor and associated circuitry (e.g., Input/Output (“IO”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“IO”) circuitry, power delivery circuitry, etc.) arranged in a disaggregated collection of discrete dies, tiles and/or chiplets (e.g., one or more discrete processor core die arranged adjacent to one or more other die such as memory die, IO die, etc.). In such disaggregated devices and systems, the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Italicized letters, such as ‘i’, ‘j’, ‘k’, ‘m’, ‘n’, etc. in the foregoing detailed description are used to depict an integer number, and the use of a particular letter is not limited to particular embodiments. Moreover, the same letter may be used in separate claims to represent separate integer numbers, or different letters may be used. In addition, use of a particular letter in the detailed description may or may not match the letter used in a claim that pertains to the same subject matter in the detailed description.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A System on a Chip (SoC) comprising:
a plurality of memory channels having input-output (IO) interface circuitry comprising a plurality of signals, including,
a first subset of signals associated with a first subchannel including a first set of command and address (C/A) signals, and a first set of data lines;
a second subset of signals associated with a second subchannel including a second set of C/A signals, and a second set of data lines; and
and at least one clock signal to be used as a command-bus clock for at least one of the first and second sets of C/A signals.

2. The SoC of claim 1, wherein circuitry is laid out on an SoC die such that the IO interface circuitry for the memory channels includes clock circuitry that is proximate to the IO circuitry for the first and second subchannels, and wherein the clock circuitry for a first memory channel is configured to provide a command-bus clock signal for a Dynamic Random Access Memory (DRAM) Dual Inline Memory Module (DIMM) that is connected to at least one subchannel for a second memory channel.

3. The SoC of claim 2, wherein clocks for pairs of adjacent memory channel IO interfaces are swapped such that the clock circuitry for a first memory channel IO interface is used with the C/A signals for a second memory channel IO interface and the clock circuitry for the second memory channel IO is used with the C/A signals for the first memory channel IO interface.

4. The SoC of claim 1, wherein each memory channel includes associated clock circuitry and the IO circuitry for sequential memory channels occupy a vertical or horizontal edge of an SoC die, and wherein a skip 1 configuration is used under which clock circuitry associated with a first given memory channel is used to provide a command-bus clock signal for the C/A signals for a second given memory channel that is separated from the first given memory channel by one memory channel disposed therebetween.

5. The SoC of claim 1, wherein each memory channel includes associated clock circuitry and the IO circuitry for sequential memory channels occupy a vertical or horizontal edge of an SoC die, and wherein a skip 2 configuration is used under which clock circuitry associated with a first given memory channel is used to provide a command-bus clock signal for the C/A signals for a second given memory channel that is separated from the first given memory channel by two memory channels disposed therebetween.

6. The SoC of claim 1, wherein each memory channel includes associated clock circuitry and the IO circuitry for sequential memory channels occupy a vertical or horizontal edge of an SoC die, and wherein a skip 3 configuration is used under which clock circuitry associated with a first given memory channel is used to provide a command-bus clock signal for the C/A signals for a second given memory channel that is separated from the first given memory channel by three memory channels disposed therebetween.

7. The SoC of claim 1, wherein the SoC comprises one or more dies, and wherein the clock circuitry for a given die is configured such that the clock signals for at least two memory channels are synchronized.

8. A system, comprising:
a printed circuit board (PCB) or substrate;
a System on a Chip (SoC) mounted to the PCB or substrate comprising a plurality of memory channels having input-output (IO) interface circuitry comprising a plurality of signals, including,
a first subset of signals associated with a first subchannel including a first set of command and address (C/A) signals, and a first set of data lines;
a second subset of signals associated with a second subchannel including a second set of command and address (C/A) signals, and a second set of data lines; and
and at least one command-bus clock signal to be used with the first and second sets of C/A signals;
a plurality of Dynamic Random Access Memory (DRAM) Dual Inline Memory Modules (DIMMs) operative coupled to the PCB or substrate, each DRAM DIMM including interface circuitry to support two subchannels, each subchannel having a respective set of C/A signals and data lines, each DRAM DIMM further having at least one registered clock driver RCD) input,
wherein the PCB or substrate includes wiring connecting the set of C/A signals and data lines associated with each subchannel to a respective subchannel interface on a DRAM DIMM.

9. The system of claim 8, wherein a DRAM DIMM includes first and second RCD inputs, each associated with C/A signals corresponding to a respective subchannel.

10. The system of claim 9, wherein clock circuitry associated with a first memory channel on the SoC is coupled to first RCD inputs for a pair of DRAM DIMMs, and wherein clock circuitry associated with a second memory channel on the SoC is coupled to second RCD inputs for the pair of DRAM DIMMs via wiring in the PCB or substrate.

11. The system of claim 8, wherein the SoC includes one or more dies, wherein circuitry is laid out on an SoC die such that each memory channel IO interface circuitry includes clock circuitry that is proximate to the IO circuitry for the first and second subchannels, and wherein the clock circuitry for a first memory channel is configured to provide a command-bus clock signal that is received at an RCD input for a DRAM DIMM that is connected to at least one subchannel for a second memory channel.

12. The system of claim 11, wherein clocks for pairs of adjacent memory channel IO interfaces are swapped on an SoC die such that the clock circuitry for a first memory channel IO is used with the C/A signals for a second memory channel IO and the clock circuitry for the second memory channel IO is used with the C/A signals for the first memory channel IO.

13. The system of claim 8, wherein the C/A signals and data signals for first and second subchannels associated with a set of memory channel are connected to IO interface circuitry for respective first and second subchannels on respective DRAM DIMMs.

14. The system of claim 8, wherein each memory channel includes associated clock circuitry and the IO circuitry for sequential memory channels occupy a vertical or horizontal edge of an SoC die, and wherein a skip 2 configuration is used under which clock circuitry associated with a first given memory channel is used to provide a command-bus clock signal for the C/A signals for a subchannel associated with a second given memory channel that is separated from the first given memory channel by two memory channels disposed therebetween.

15. The system of claim 8, wherein each memory channel includes associated clock circuitry and the IO circuitry for sequential memory channels occupy a vertical or horizontal edge of an SoC die, and wherein a skip 3 configuration is used under which clock circuitry associated with a first given memory channel is used to provide a command-bus clock signal for the C/A signals for a subchannel associated with second given memory channel that is separated from the first given memory channel by three memory channels disposed therebetween.

16. A memory module comprising:
memory channel input-output (TO) interface circuitry configured to interface with (IO) circuitry for first and second memory subchannels, comprising at least one command-bus clock signal and respective first and second sets of signal lines for the first and second subchannels including Command/Address (C/A) signal lines and a DQ lines;
at least one registered clock driver (RCD) component; and
a plurality of Dynamic Random Access Memory (DRAM) devices, each comprising,
IO circuitry coupled to the IO interface circuitry comprising a plurality of signal lines including one or more clock signal lines, a set of C/A signal lines, and a set of DQ lines; and
a plurality of bank groups, each bank group comprising multiple memory banks, each memory bank including a plurality of memory cells arranged in rows and columns,
wherein the set of C/A signal lines and set of DQ lines for a DRAM device are split and operated as first and second subchannels.

17. The memory module of claim 16, wherein the at least one RCD component comprises first and second RCD components.

18. The memory module of claim 17, wherein the first RCD component provides one or more command-bus clock inputs for a first subchannel and the second RCD component provides one or more command-bus clock inputs for a second subchannel, and wherein the first and second subchannels are configured to operate independently.

19. The memory module of claim 17, wherein the memory module comprises a dual inline memory module (DIMM) having a connector with a plurality of pins including MCR pins, and wherein one of the first and second RCD components is coupled to MCR pins on a connector.

20. The memory module of claim 16, wherein the set of DQ lines are split into two subsets of DQ lines operated as separate subchannels having a width of eight bits.
